(19) United States
(12) Patent Application Publication
(10) Pub. No.: US 2012/0285622 A1
(43) Pub. Date: Nov. 15, 2012

(54) PLASMA DEVICE

(76) Inventors: Ji Man LIM, Asan-si (KR); Jae-Woo Lee, Jangseong-gun (KR); Jun Seo, Asan-si (KR); Dae Young Han, Asan-si (KR)

(21) Appl. No.: 13/419,287

(22) Filed: Mar. 13, 2012

(30) Foreign Application Priority Data
May 9, 2011 (KR) 10-2011-0043511

(51) Int. Cl. H01L 21/3065

(52) U.S. Cl. 156/345.47

(57) ABSTRACT

A plasma device includes: a reaction chamber; an upper electrode positioned upward in the reaction chamber; a lower electrode facing the upper electrode; a baffle plate enclosing the lower electrode and including a plurality of cutouts formed at the edge thereof, wherein a boundary line of the cutout is connected to a boundary line of the baffle plate, thereby forming a recess portion at the edge of the baffle plate. The cutouts of the baffle plate change the flow of the reactive gas in the chamber, helping achieve a more uniform etch.

### CROSS-REFERENCE TO RELATED APPLICATION

This application claims priority to and the benefit of Korean Patent Application No. 10-2011-0043511 filed in the Korean Intellectual Property Office on May 9, 2011, the entire contents of which are incorporated herein by reference.

### BACKGROUND OF THE INVENTION

(a) Field of the Invention

The present invention relates to a plasma device.

(b) Description of the Related Art

A thin film transistor (TFT) is used in various fields, and is particularly used as switching and driving elements in a flat panel display such as a liquid crystal display (LCD), an organic light emitting device (OLED) display, and an electrophoretic display.

A thin film transistor includes a gate electrode connected to a gate line transmitting a scanning signal, a source electrode connected to a data line transmitting a signal applied to a pixel electrode, a drain electrode facing the source electrode, and a semiconductor electrically connected to the source electrode and the drain electrode.

The wires and electrodes that connect a thin film transistor to other components are formed by depositing a thin film on a substrate and patterning a desired shape through an etching process. The etching method may be wet etching or dry etching. Dry etching generally uses plasma.

A plasma processing device includes a reaction chamber, an upper electrode and a lower electrode facing each other in the reaction chamber, a high frequency power source applying power to the upper and lower electrodes to generate plasma, and a baffle plate uniformly distributing the plasma generated in the reaction chamber and letting the reaction residue flow toward the exit.

A reaction gas supplied to the reaction chamber is changed to a plasma state by using the high frequency power that is applied to the upper and lower electrodes through a high frequency power source. The reaction gas, once converted to plasma state, etches a surface of an LCD panel (hereinafter referred to as “a substrate”). Here, when moving the lower electrode upward to execute the etching process, a baffle plate uniformly exhausts a non-reaction gas and a polymer inside the reaction chamber to a lower side of the reaction chamber.

The baffle plate provided is fixed to the inner wall of the chamber under a gate door where the substrate is input and output, causing the plasma formed inside the reaction chamber to leak to the outside of the lower electrode. Particularly, the plasma becomes more concentrated around the gate door when the lower electrode loaded with the substrate is moved upward to execute the plasma process and the plasma is formed between the upper electrode and the lower electrode.

The plasma in the chamber is non-uniformly distributed due to this phenomenon such that the edge of the substrate becomes over-etched, and this is represented as a spot of the liquid crystal display.

The above information disclosed in this Background section is only for enhancement of understanding of the background of the invention and therefore it may contain information that does not form the prior art that is already known in this country to a person of ordinary skill in the art.

### SUMMARY OF THE INVENTION

A plasma device that uniformly etches a substrate is presented.

In one aspect, the invention is a plasma device that includes: a reaction chamber; an upper electrode positioned in the reaction chamber; a lower electrode facing the upper electrode; and a baffle plate enclosing the lower electrode and including an edge having a plurality of cutouts forming a recess portion at the edge of the baffle plate.

A focusing ring may be positioned on the lower electrode, wherein the cutout is spaced from an imaginary extension line extending from an edge of the focusing ring by 1.3 times to 1.9 times the diameter of the cutout.

The size of the cutout may be 1/18 times to 1/23 times a long axis length of the baffle plate.

The baffle plate may be quadrangular.

The cutout may have a semi-circular cross section.

Each cutout may include a plurality of slits.

The lower electrode may include a substrate elevator and an electrostatic chuck configured to support a substrate.

A ratio of the baffle plate area to a cutout area is between 100:18 and 100:0.

According to an exemplary embodiment of the present invention, the substrate is uniformly etched in the plasma device such that the display quality of the liquid crystal display may be improved.

### BRIEF DESCRIPTION OF THE DRAWINGS

The patent or application file contains at least one drawing executed in color. Copies of this patent or patent application publication with color drawings will be provided by the U.S. Patent and Trademark Office upon request and payment of the necessary fee.

FIG. 1 is a schematic cross-sectional view of a plasma device including a baffle plate according to an exemplary embodiment of the present invention.

FIG. 2 is a perspective view of a lower electrode part of a plasma device including a baffle plate according to the present invention.

FIG. 3 is a top plan view of a cutout according to another exemplary embodiment of the present invention.

FIG. 4 is a view of a simulation of turbulence energy when using a baffle plate according to an exemplary embodiment of the present invention.

FIG. 5 is a view of a simulation of surface stress when using a baffle plate according to an exemplary embodiment of the present invention.

### DETAILED DESCRIPTION OF THE EMBODIMENTS

The present invention will be described more fully hereinafter with reference to the accompanying drawings, in which exemplary embodiments of the invention are shown. As those skilled in the art would realize, the described embodiments may be modified in various ways without departing from the spirit or scope of the present invention.

In the drawings, the thickness of layers, films, panels, regions, etc., are exaggerated for clarity. Like reference numerals designate like elements throughout the specification. It will be understood that when an element such as a layer, film, region, or substrate is referred to as being “on” another element, it can be directly on the other element or intervening elements may also be present. In contrast, when an element is referred to as being “directly on” another element, there are no intervening elements present.

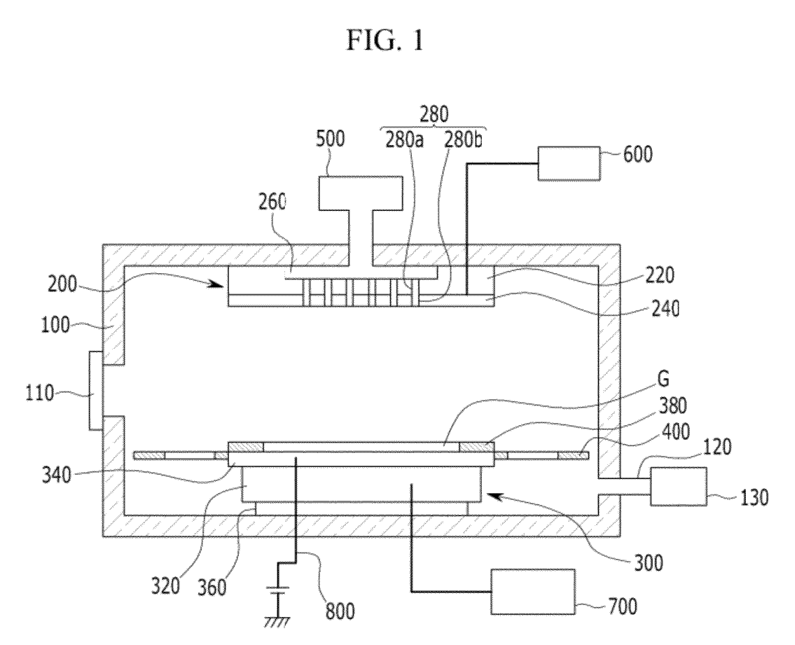

Thus, a plasma device according to an exemplary embodiment of the present invention will be described with reference to FIG. 1 to FIG. 3.

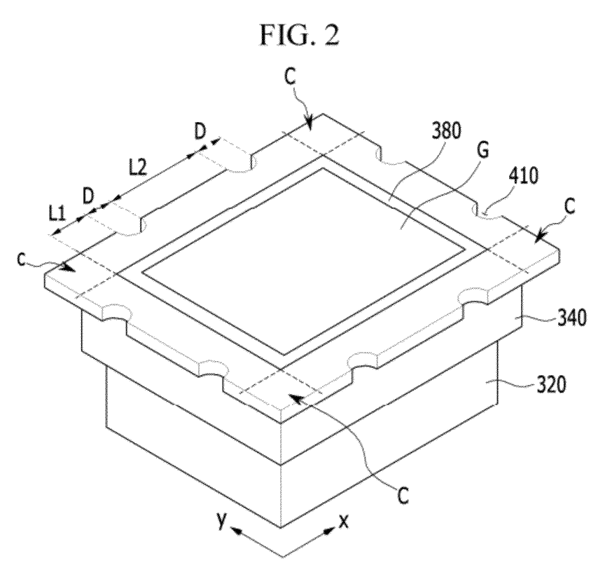

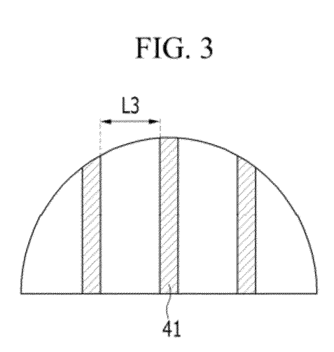

FIG. 1 is a schematic cross-sectional view of a plasma device including a baffle plate according to an exemplary embodiment of the present invention, FIG. 2 is a perspective view of a lower electrode part of a plasma device including a baffle plate according to the present invention, and FIG. 3 is a top plan view of a cutout according to another exemplary embodiment of the present invention.

Referring to FIG. 1, a plasma device of the present invention includes a reaction chamber 100, an upper electrode part 200 and a lower electrode part 300 facing each other in the reaction chamber 100, and a baffle plate 400. The lower electrode part 300 includes a substrate elevator 320 and an electrostatic chuck 340. The baffle plate 400 fits around the electrostatic chuck 340.

The reaction chamber 100 provides a closed and sealed space while an etching process is executed. A gate door 110 to load and unload a substrate G is formed at one side of the reaction chamber 100. In FIG. 1, one gate door 110 is formed at one side of the reaction chamber 100. However, this is not a limitation of the invention, and the gate door 110 may be formed at both sides, thereby separately executing loading and unloading.

The reaction chamber 100 is connected to an exhaust means through which gas inside the reaction chamber 100 exit the chamber 100 during the etching process. The exhaust means includes an exhaust port 120 and an exhaust device 130.

The upper electrode part 200 includes an insulating supporting member 220 positioned in the reaction chamber 100 and an upper electrode plate 240 coupled to a lower surface of the insulating supporting member 220. The insulating supporting member 220 is formed with an inner space 260 that is empty, and a plurality of gas discharge holes 280a that are formed under the inner space 260.

The upper electrode plate 240 is made of aluminum and includes gas discharge holes 280b connected to the gas discharge holes 280a formed at the insulating supporting member 220 and extending through the upper electrode plate 240.

A gas supplying unit 500 and an upper high frequency power source part 600 to generate the plasma are connected to the upper electrode part 200.

The gas supplying unit 500 includes a gas supplying source (not shown) and a mass flow controller (MFC, not shown) such that the gas supplied from the gas supplying source is supplied to the inner space 260 formed at the upper electrode part 200 by controlling the desired amount by the MFC. Also, the upper high frequency power source unit 600 includes an upper high frequency power source (not shown) and an upper equalizer (not shown) such that substantially the same power level that is supplied from the high frequency power source is supplied to the upper electrode plate 240.

Accordingly, if the gas and the high frequency power are supplied and applied to the upper electrode part 200, the gas that is input to the upper electrode part 200 sprays out through the gas discharge holes 280. As shown in FIG. 1, the gas discharge holes 280 extend vertically through the insulating supporting member 220 and the upper electrode plate 240 through the inner space 260 formed in the insulating supporting member 220. The plasma is formed between the upper electrode part 200 and the lower electrode part 300.

A sealed ring (not shown) may be further provided to fit around the side surfaces of the upper electrode part 200. The sealed ring would prevent abnormal discharge that may be generated in the upper electrode part 200, and is formed to fit around the side surfaces of the upper electrode plate 240 and the insulating supporting member 220. Due to the presence of the upper electrode plate 240, the lower surface of the upper electrode plate 240 is not exposed.

Meanwhile, the lower electrode part 300 includes the substrate elevator 320 separated from the upper electrode part 200 by a predetermined distance and the electrostatic chuck 340 formed on the substrate elevator 320. Here, the substrate elevator 320 is connected to a lower high frequency power source part 700, and the electrostatic chuck 340 is connected to a high voltage DC power source 800.

The substrate elevator 320 supports the electrostatic chuck 340, and a lift means 360 is connected under the substrate elevator 320 to move the electrostatic chuck 340 up and down. Also, a lower electrode plate (not shown) is formed inside the substrate elevator 320, and the lower electrode plate is connected to the lower high frequency power source part 700. The high frequency power source part 700 includes a lower high frequency power source (not shown) and a lower matcher (not shown), and a function thereof is the same as that of the upper high frequency power source part 600. Here, a cooling member (not shown) to control the temperature of the lower electrode part 300 may be further formed inside the substrate elevator 320.

The electrostatic chuck 340 is provided on the substrate elevator 320. The electrostatic chuck 340 may be formed in a shape that is similar to the shape of the substrate G that may be mounted on the upper surface of the electrostatic chuck 340. The electrostatic chuck 340 attaches and fixes the substrate G loaded inside the reaction chamber 100. That is, the electrostatic chuck 340 is connected to the high voltage DC power source 800, thereby attaching and maintaining the substrate G by the electrostatic force formed by the high voltage DC power source 800. The substrate is attached to and held in place by the electrostatic force of the electrostatic chuck 340. However, using electrostatic force to hold the substrate in place is not a limitation of the invention and a mechanical chuck using vacuum force or mechanical force may be used.

A focusing ring 380 may be further provided according to the external circumferential surface of the substrate G loaded on the electrostatic chuck 340. The focusing ring 380 is formed according to the external circumferential surface of the substrate G, thereby concentrating the reaction gas of the plasma state formed inside the reaction chamber 100 to the substrate G.

Meanwhile, the baffle plate 400 is installed around and in contact with the external circumferential surface of the electrostatic chuck 340. The baffle plate 400 uniformly moves the reaction gas supplied inside the reaction chamber 100 downward such that the flow of the reaction gas around the substrate G mounted to the electrostatic chuck 340 is constantly maintained. By maintaining the concentration of reaction gas around the substrate G substantially constant, the baffle plate 400 helps achieve uniform etching on the substrate G.

Referring to FIG. 2, the baffle plate 400 has an approximately quadrangular planer shape. The baffle plate 400 includes an opening (not shown) into which the electro-static chuck 340 is inserted. The external circumferential surface of the baffle plate 400 is approximately the same size as the inner wall of the reaction chamber 400, and the interior circumference (i.e., the size of the opening) is approximately the same size as that of the external circumferential surface of the electrostatic chuck 340.

A plurality of cutouts 410 through which the gas passes are formed in the baffle plate 400 such that the reaction gas inside the reaction chamber 100 is uniformly moved under the baffle plate 400 and out of the reaction chamber 100.

The cutouts 410, which may have a semi-circular cross section, are formed along the edges of the baffle plate 400, in the form of a recess portion at the edges of the baffle plate 400. The diameter of each cutout 410 may be about 1/18 times to 1/23 times of the long axis (X-axis) length of the baffle plate 400. For example, if the long axis length of the baffle plate is 2740 mm, the diameter of the cutout 410 may be 134 mm.

The cutout 410 is positioned close to the corner C of the baffle plate 400 from a position bisecting each edge of the baffle plate 400. That is, a distance L1 is preferably 1.3 times to 1.9 times the diameter of the cutout 410, wherein the distance L1 is measured from an imaginary extension of an edge of the focusing ring 380 to the nearest point of the cutout 410.

Table 1 shows experimental data on etching uniformity for an area of all the corners of a baffle plate and an area of all the cutouts according to an exemplary embodiment of the present invention.

TABLE 1

| Ratio Corner area:Cutout area | Uniformity |
|---|---|
| 100:0 | 24.5% |
| 100:25 | 22.8% |
| 100:20 | 21.3% |
| 100:19 | 17.9% |
| 100:18 | 16.7% |

Referring to Table 1, in the baffle plate 400, it may be confirmed that as the ratio of the corner area: the cutout area changes to 100:25, 100:20, 100:19, and 100:18, the uniformity is increased.

Accordingly, it is preferable that the ratio of the corner area: cutout area is larger than 100:0 and less than 100:18.

In the exemplary embodiment of the present invention, the cutouts 410 are formed with constant diameter. However, cutouts having different diameters may be formed when considering the ratio of the baffle plate area and the cutout area.

Accordingly, in the exemplary embodiment of the present invention, the cutouts are formed to have a semicircular cross section, however they may be formed to have a quadrangular or oval cross section when considering the area ratio.

Also, as shown in FIG. 3, each cutout 410 includes a plurality of slits 41, and the interval L3 between the slits 41 is less than the width of the above-described cutouts 410. Though the diameter of the cutouts 410 is larger than the above-described value (that is, 1/23 times of the long axis (X-axis) length of the baffle plate), if a plurality of slits 41 are formed, since the diameter of the cutouts 410 is decreased by parts between the slits 41, the etching may be uniformly executed.

The gas inserted inside the chamber flows under the substrate through a pumping port positioned at the corner of the baffle plate, and is then discharged through the exhaust port 120. Due to the gas flow, the portion of the substrate positioned near the pumping port may be over-etched when etching the substrate. The pumping port as a portion enclosed by an extension line (a dotted line) of the focusing ring in FIG. 2 is positioned at the corner of the baffle plate.

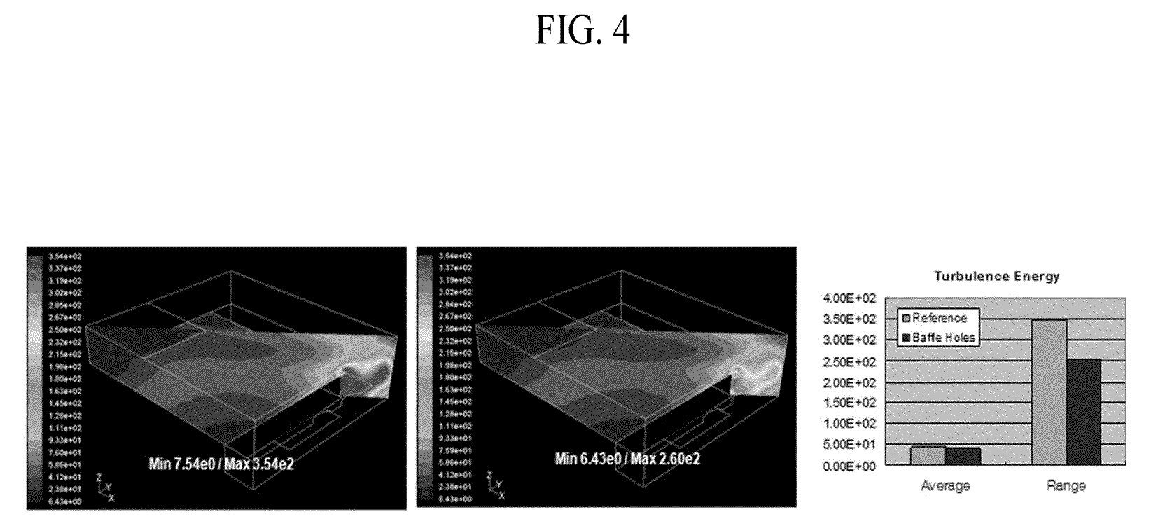

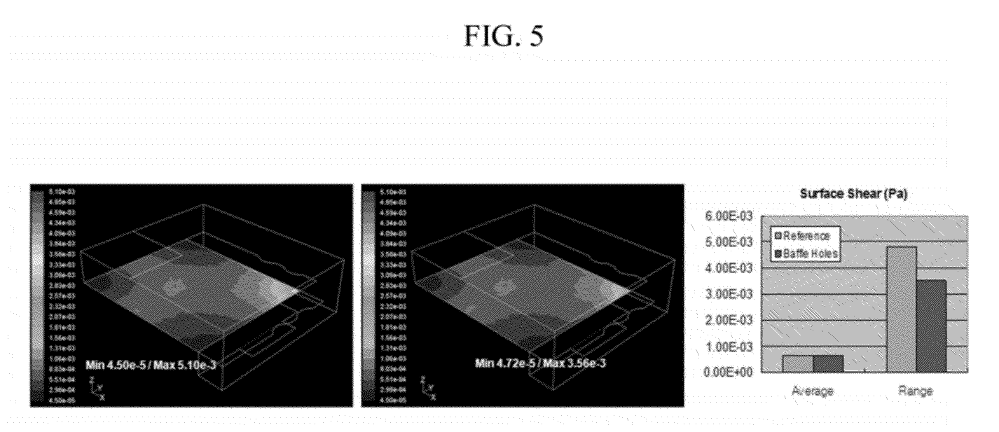

However, as shown in an exemplary embodiment of the present invention, if the baffle plate including a cutout positioned near the pumping port is installed, the flow pattern of fluid in the reaction chamber is changed such that over-etching of the substrate near the pumping port may be prevented. Accordingly, the entire substrate may be uniformly etched. As shown in FIG. 4 and FIG. 5, when measuring the surface stress, the averages of the surface stresses of a conventional art and the present invention are found to be the same. However, it may be confirmed that the distribution range of the surface stress according to the present invention is narrower than the conventional art. That is, the changing width of the surface stress is decreased by the baffle plate according to the present invention such that uniform etching may be executed for the entire substrate.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

<Description of Symbols>

| | |
|---|---|
| 41: slit | 100: chamber |
| 110: gate door | 120: exhaust port |
| 130: exhaust device | 200: upper electrode part |
| 220: insulating supporting member | 240: upper electrode plate |
| 280: discharge holes | 300: lower electrode part |
| 320: substrate elevator | 340: electrostatic chuck |
| 380: focusing ring | 400: baffle plate |
| 410: cutout | 500: gas supplying unit |

600, 700: high frequency power source part

What is claimed is:

1. A plasma device comprising:
a reaction chamber;
an upper electrode positioned in the reaction chamber;
a lower electrode facing the upper electrode; and
a baffle plate enclosing the lower electrode and including an edge having a plurality of cutouts,
forming a recess portion at the edge of the baffle plate.

2. The plasma device of claim 1, further comprising
a focusing ring positioned on the lower electrode, wherein
the cutout is spaced from an imaginary extension line extending from an edge of the focusing ring by 1.3 times to 1.9 times the diameter of the cutout.

3. The plasma device of claim 2, wherein
the size of the cutout is 1/18 times to 1/23 times a long axis length of the baffle plate.

4. The plasma device of claim 1, wherein
the baffle plate is quadrangular.

5. The plasma device of claim 1, wherein
the cutout has as semi-circular cross section.

6. The plasma device of claim 1, wherein
each cutout includes a plurality of slits.

7. The plasma device of claim 1, wherein
the size of the cutout is in the range of 1/18 times to 1/23 times the long side of the baffle plate.

8. The plasma device of claim 1, wherein the lower electrode comprises a substrate elevator and an electrostatic chuck configured to support a substrate.

9. The plasma device of claim 1, wherein
a ratio of a corner area: a cutout area is between 100:0 and 100:18.
